(19) United States
(12) Patent Application Publication
(10) Pub. No.: US 2026/0223270 A1
(43) Pub. Date: Jul. 30, 2026

(54) MICRO-LED WITH INTEGRATED CAN BUS AND ACTUATORS IN TRANSPORTATION VEHICLES

(71) Applicant: VueReal Inc., Waterloo (CA)

(72) Inventors: Gholamreza CHAJI, Waterloo (CA); John CRONIN, Jericho, VT (US)

(73) Assignee: VueReal Inc., Waterloo, ON (CA)

(21) Appl. No.: 19/142,509

(22) PCT Filed: Dec. 22, 2023
(86) PCT No.: PCT/CA2023/051752

§ 371 Date: Jun. 23, 2025

Related U.S. Application Data
(60) Provisional application No. 63/477,080, filed on Dec. 23, 2022.

(51) Int. Cl. H05B 47/18; B60Q 1/14; H05B 45/10; H10H 29/14

(52) U.S. Cl. CPC H05B 47/18; H05B 45/10; H10H 29/142; B60Q 1/1423

(57) ABSTRACT

The present disclosure provides integrating micro-LEDs with CAN bus and actuators in which a micro-LED unit contains a substrate, a plurality of micro-LEDs, a memory, a processor, a CAN bus module, and a CAN bus. The CAN bus module is continuously polling to start, reads a data message received from the CAN bus, stores the data in memory, determines the appropriate controller for the micro-LED tiles, and activates, terminates, or adjust the settings of the micro-LED tile.

### BACKGROUND AND FIELD OF THE DISCLOSURE

The present disclosure generally relates to integrating micro-LEDs with a CAN bus in transportation vehicles.

The transportation industry is any industry, business, or establishment operated to convey persons or property from one place to another, whether by rail, highway, air, or water, and all operations and services in connection in addition to that; and also includes storing or warehousing of goods or property, and the repairing, parking, rental, maintenance, or cleaning of vehicles.

Currently, a CAN bus in a vehicle is a robust vehicle bus standard designed to allow microcontrollers and devices to communicate with each other's applications without a host computer. Also, lighting systems in vehicles are activated or terminated with the use of an actuator.

Lastly, micro-LEDs require specific control signals to produce the correct lighting needed for certain situations, especially when using a vehicle.

Thus, there is a need in the prior art to integrate micro-LEDs with a CAN bus and actuators in transportation vehicles.

### SUMMARY

The present invention relates to a method to integrate a micro-LED unit with CAN bus, comprising, having a substrate, having a plurality of micro-LEDs, having a CAN bus module, having a memory, having a processor and having a CAN bus, wherein, the CAN bus module is continuously polling to start, reads a data message received from the CAN bus, stores the data in memory, determines the appropriate controller for micro-LED tiles, and activates, terminates, or adjusts the settings of the micro-LED tile.

### DESCRIPTIONS OF THE DRAWINGS

FIG. 1: Illustrates an integration of a transferred micro-device with an electro-optical thin film device in a hybrid structure, according to an embodiment.

FIG. 2: Illustrates a basic CAN bus connection, according to an embodiment.

FIG. 3: Illustrates a micro-LED CAN bus connection for on, off, and dim, according to an embodiment.

FIG. 4: Illustrates a micro-LED CAN bus connection for zone control, according to an embodiment.

FIG. 5: Illustrates a micro-LED CAN bus connection for RGB control, according to an embodiment.

### DETAILED DESCRIPTION

Embodiments of the present disclosure will be described more fully hereinafter with reference to the accompanying drawings in which like numerals represent like elements throughout the several figures, and in which example embodiments are shown. Embodiments of the claims may, however, be embodied in many different forms and should not be construed as limited to the embodiments set forth herein. The examples set forth herein are non-limiting examples and are merely examples among other possible examples.

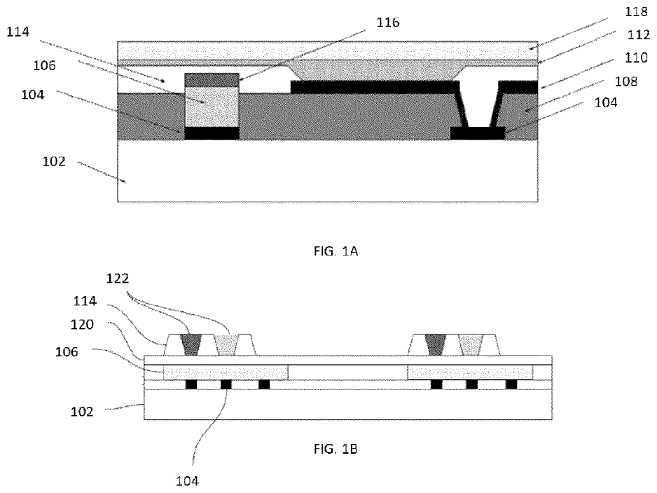

FIG. 1A shows an example of integrating a transferred micro-device 106 with an electro-optical thin film device 112 in a hybrid structure. This is an example of an integrated micro-led tile that is later picked and placed into an array of tiles. It should be obvious to those in the art there are many ways to create micro-led tiles and integrate them in an array of tiles, as per US20160218143A1—Microdevice integration into system substrate. A receiver substrate 102 and contact pads 104 upon which the microdevice 106 arrays are transferred and into which the thin film electro-optical device is integrated in a number of hybrid structure embodiments. Microdevice 106 may be transferred and bonded to the bonding pad 104 of the receiver substrate 100. In one case, a dielectric layer 108 is formed over the substrate 102 to cover the exposed electrodes and conductive layers. Lithography and etching may be used to pattern the dielectric layer 108. Conductive layer 110 is then deposited and patterned to form the bottom electrode of the thin film electro-optical device 112. If there is no risk of unwanted coupling between bottom electrode 110 and other conductive layers in the receiver substrate, the dielectric layer 108 may be eliminated. However, this dielectric layer can also act as a planarization layer to offer better fabrication of electro-optical devices 112. A bank layer 114 is deposited on the substrate 102 to cover the edges of the electrode 110 and the microdevice 106. Thin film electro-optical device 112 is then formed over this structure. Organic LED (OLED) devices are an example of a thin film electro-optical device that may be formed using different techniques such as but not limited to shadow mask, lithography, and printing patterning. Finally, the top electrode 118 of the electro-optical thin film device 112 is deposited and patterned if needed. In an embodiment where the microdevices' 106 thickness is significantly high, cracks or other structural problems may occur within the bottom electrode 110. In these embodiments, a planarization layer may be used in conjunction with or without the dielectric layer 108 to address this issue. In another embodiment, the microdevice 106 can have a device electrode 116. This electrode can be common between other microdevices 106 in the system substrate. In this case, the planarization layer (if present) and/or bank structure 114 covers the electrode 116 to avoid any shorts between the electro-optical device 112 and device electrode 116.

FIG. 1B illustrates structures where the device is shared between a few pixels (or sub-pixels) after post-processing to deposit a common electrode and color conversion layers. Here the microdevice 106 is not fully patterned, but the horizontal condition is engineered so that the contacts 104 define the area allocated to each pixel. The system substrate 102 with contact pads 104 and a donor substrate with microdevices 106. After the microdevices 106 are transferred to system substrate 102, one can do post-processing, such as depositing common electrode 120, color conversion layers 122, color filters, and so on. However, the methods described in this disclosure and other possible methods can be used. It is possible to add the color conversion layers as described into pixel (or sub-pixel) active areas after forming the active area. This can offer a higher fill factor and higher performance and avoid color leaking from the side pixel (or sub-pixel) if the active area of the pixel (or sub-pixel) is covered by reflective layers. The microdevices 106 are grown on a buffer/sacrificial layer in another embodiment.

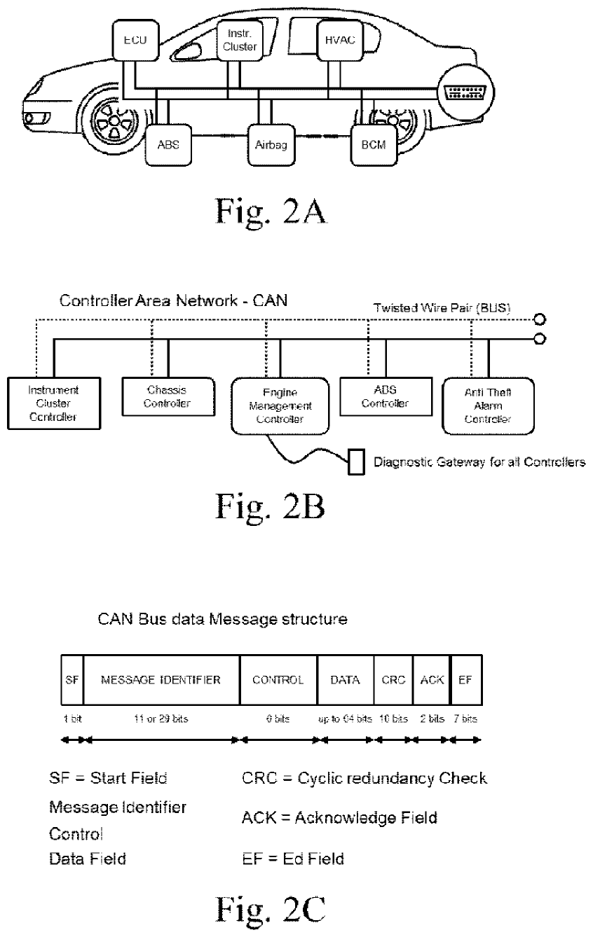

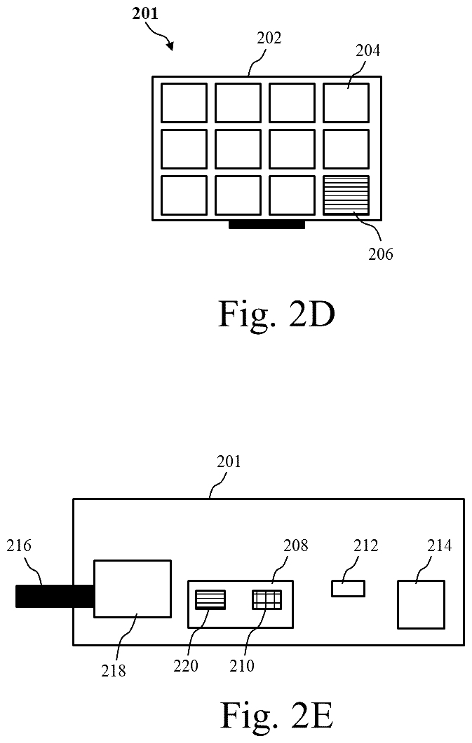

FIG. 2 illustrates embodiments of basic CAN bus connection. FIG. 2A displays an embodiment of the CAN (controller area network) bus. The CAN bus improves performance and safety by enabling a faster flow of real-time data around the car. The CAN bus network combines messages, reducing the amount of electrical wiring (and weight) required. A CAN bus allows any network device to create a “data frame,” the standard message format, and transmit it sequentially. If more than one device transmits simultaneously, the highest priority device continues while the others wait. Frames are received by all ECU nodes in the network and consist of an ID, a message, and other items such as error correction bits. The value of the CAN identifier (CAN-ID) indicates the priority level. The lower the number, the higher the priority. The ID relates to specific items and activities, such as switching lights on or off or a particular sensor. The physical network on most cars is made up of a twisted pair of thin wires known as CAN high (CAN-H) and CAN low (CAN-L). Coaxial cables and fiber optics can also be used. Using a gateway to control data traffic, most vehicles now have several different networks—for the body, the powertrain, and the infotainment system, for example. Vehicles may have dozens of ECUs, including ones for the engine, the transmission control, the airbags, the ABS, the traction control, and the stability control. The CAN bus allows these areas to communicate in real-time, prioritizing the most important information and helping improve vehicle safety and performance. FIG. 2B displays an embodiment of a schematic diagram of a CAN system and examples of the units or devices that can be connected to the CAN bus. For example, the CAN system may connect the instrument controller, chassis controller, engine management controller, anti-brake system (ABS) controller, anti-theft alarm controller, etc. Typically, the CAN bus comprises two wires, CAN High, or CAN-H, and CAN Low, or CAN-L, which connect to all the devices in the network. The signals on the two CAN lines have the same data sequence, but their amplitudes are opposite to prevent noise from corrupting the data. The CAN is a vehicle bus standard designed to allow electronic control units and devices to communicate with each other in applications without a host computer. As an alternative to conventional multi-wire looms, the CAN bus allows various electronic components, such as electronic control units, microcontrollers, devices, sensors, actuators, and other electronic components throughout the vehicle to communicate on a single or dual-wire network data bus up to 1 Mb/s. The CAN bus is a message-based protocol designed originally for multiplex electric wiring within motor vehicles but can also be used in many other contexts. FIG. 2C displays an embodiment of the CAN bus data message structure. The “SF” is the start field that indicates the beginning of a message with a dominant bit and marks the start of the data protocol. The message identifier defines the level of priority of the data protocol. For example, if two CAN nodes send their data protocol simultaneously, the CAN node with the higher priority will take precedence. The lower value for the CAN node indicates a higher priority. The control, which may be the check field, displays the number of items of information in the data field, allowing any receiver to check whether it has received all the information transferred to it. The data field contains the information that is transferred to other CAN nodes. The “CRC” is the cyclic redundancy check that contains a 15-bit cyclic redundancy check code and a recessive delimiter bit and is used to detect transfer faults. The “ACK” is the acknowledge field in which the receivers signal to the transmitter that they have correctly received the data protocol, and if there is an error, the receivers notify the transmitter, which prompts the transmitter to resend the data protocol. The “EF” is the end field that marks the end of the data protocol and is the last possibility to indicate an error has occurred. FIG. 2D displays an embodiment of a basic CAN bus module 201 in which a micro-LED unit is connected to a vehicle's CAN bus to receive instructions for activating, deactivating, adjusting the micro-LED tiles' brightness, etc. The basic CAN bus module 201 may include a substrate 202, a micro-LED tile 204, a CAN bus tile 206, memory 208, basic CAN bus module 210, the bus controller 212, processor 216, CAN bus twisted pair 216, CAN bus controller and decoder 218, and CAN bus application module 220. The substrate 202 may be made of glass, silicon, plastics, or any other commonly used material. The substrate 202 may also have active electronic components such as but not limited to transistors, resistors, capacitors, or any other electronic component commonly used in a system substrate. In some cases, the substrate 202 may be a substrate 202 with electrical signal rows and columns. In one example, the substrate 202 may be a sapphire substrate with LED layers grown monolithically on top of it, and the substrate 202 may be a backplane with circuitry to derive micro-LED devices. In some embodiments, the substrate 202 may be a flexible or rigid substrate 202. The micro-LED tile 204 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED tile 204 may be produced in a plurality of sizes to increase the width or length of the micro-LED tile 204. The micro-LED tiles 204 may include a plurality of connectors which may be an electrochemical device used to create an electrical connection between the plurality of micro-LED tiles, which create the micro-LED tile 204. The connectors may receive power, data signals, informational instructions, etc., from the ribbon connector to power and control the individual micro-LEDs in the micro-LED tiles 204 that make up the micro-LED unit. The CAN bus tile 206 may be integrated with the micro-LED tile 204 to send and receive instructions from other vehicle applications, devices, controllers, etc. The CAN bus improves performance and safety by enabling a faster flow of real-time data around the car. The CAN bus network combines messages, reducing the amount of electrical wiring (and weight) required. A CAN bus allows any network device to create a “data frame,” the standard message format, and transmit it sequentially. If more than one device transmits simultaneously, the highest priority device continues while the others wait. Frames are received by all ECU nodes in the network and consist of an ID, a message, and other items such as error correction bits. The value of the CAN identifier (CAN-ID) indicates the priority level. The lower the number, the higher the priority. The ID relates to specific items and activities, such as switching lights on or off or a particular sensor. The physical network on most cars is made up of a twisted pair of thin wires known as CAN high (CAN-H) and CAN low (CAN-L). Coaxial cables and fiber optics can also be used. Using a gateway to control data traffic, most vehicles now have several different networks—for the body, the powertrain, and the infotainment system, for example. Vehicles may have dozens of ECUs, including ones for the engine, the transmission control, the airbags, the ABS, the traction control, and the stability control. The CAN bus allows these areas to communicate in real-time, prioritizing the most important information and helping improve vehicle safety and performance. FIG. 2E displays an additional embodiment of the basic CAN bus module 201 in which a micro-LED unit is connected to a vehicle CAN bus to receive instructions for activating, deactivating, adjusting the micro-LED tiles' brightness, etc. 204. The basic CAN bus module 201 may include a substrate 202, a micro-LED tile 204, a CAN bus tile 206, memory 208, basic CAN bus module 210, a bus controller 212, processor 216, CAN bus twisted pair 216, CAN bus controller and decoder 218, and CAN bus application module 220. The memory 208 may include, but is not limited to, fixed (hard) drives, magnetic tape, floppy diskettes, optical disks, Compact Disc Read-Only Memories (CD-ROMs), magneto-optical disks, semiconductor memories, such as ROMs, Random Access Memories (RAMs), Programmable Read-Only Memories (PROMs), Erasable PROMs (EPROMs), Electrically Erasable PROMs (EEPROMs), flash memory, magnetic or optical cards, or another type of media/machine-readable medium suitable for storing electronic instructions. The memory 208 may comprise modules implemented as a program. The basic CAN bus module 210 may begin by continuously polling to start. Then the basic CAN bus module 210 reads the CAN bus connection and decoder 218. The basic CAN bus module 210 stores the received data in memory 208. The basic CAN bus module 210 sends an acknowledgment of receiving all of the transmitted data to the CAN bus connection and decoder 218 and returns to continuously polling to start by receiving data. The bus controller 212 may be a computer bus used by the vehicle CPU to communicate with devices contained within the computer through physical connections such as cables or printed circuits. The vehicle CPU transmits various control signals to components and devices to transmit control signals to the CPU using the control bus. One of the main objectives of a bus is to minimize the lines needed for communication. The bus controller 212 may be bidirectional and assists the CPU in synchronizing control signals to internal devices and external components. It comprises interrupt lines, byte enables lines, read/write signals, and status lines. The processor 214 may be configured to decode and execute any instructions received from one or more other electronic devices or server(s). The processor 214 may include one or more general-purpose processors (e.g., INTEL® or Advanced Micro Devices® (AMD) microprocessors) and/or one or more special purpose processors (e.g., digital signal processors or Xilinx® System On Chip (SOC) Field Programmable Gate Array (FPGA) processor). The processor 214 may be configured to execute one or more computer-readable program instructions, such as program instructions, to carry out any of the functions described in this description. The CAN bus twisted pair 216 comprises two wires, CAN High, or CAN-H, and CAN Low, or CAN-L, which connect to all the devices in the network. The signals on the two CAN lines have the same data sequence, but their amplitudes are opposite to prevent noise from corrupting the data. The CAN is a vehicle bus standard designed to allow electronic control units and devices to communicate with each other in applications without a host computer. As an alternative to conventional multi-wire looms, the CAN bus allows various electronic components, such as electronic control units, microcontrollers, devices, sensors, actuators, and other electronic components throughout the vehicle to communicate on a single or dual-wire network data bus up to 1 Mb/s. The CAN bus connection and decoder may be a controller and a transceiver. The CAN bus controller may store the received serial bits from the bus until an entire message is available, which can then be fetched by the host processor. The host processor sends the transmit message(s) to a CAN controller, which transmits the bits serially onto the bus when the bus is free. The transceiver may convert the data stream from CAN bus levels to levels that the CAN controller uses. It usually has protective circuitry to protect the CAN controller and converts the data stream from the CAN controller to CAN bus levels when transmitting. The CAN bus application module 220 may be the method in which the micro-LED tile 204 connects with other applications, devices, controllers, etc., through the CAN bus of the vehicle to receive instructions to activate, terminate, adjust the settings, etc. of the micro-LED tile 204.

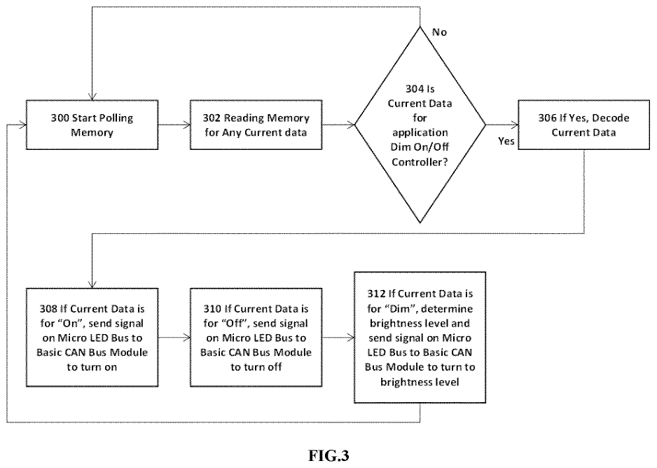

FIG. 3 illustrates an embodiment of a micro-LED CAN bus connection for on, off, and dim. The process begins with the application module 220 being executed by the processor 214. The application module 220 begins polling, and at step 300, the memory 208. The application module 220 reads, at step 302, the memory 208 for any current data. For example, the application module 220 reads the memory 208, which contains the data messages received by the basic CAN bus module 210. The messages may contain instructions or information about the micro-LED tiles 204 and whether they should be activated, terminated, or adjusted for brightness. The application module 220 determines, at step 304, if the current data is for the application dim on/off controller. If it is determined that the data stored in memory 208 is not for the dim on/off controller, then the process returns to polling the memory 208. If it is determined that the current data is for the dim on/off controller, the application module 220 decodes, at step 306, the current data. For example, the application module 220 may decode the data message structure. The “SF” is the start field that indicates the beginning of a message with a dominant bit and marks the start of the data protocol. The message identifier defines the level of priority of the data protocol. For example, if two CAN nodes send their data protocol simultaneously, the CAN node with the higher priority will take precedence. The lower value for the CAN node indicates a higher priority. The control, which may be the check field, displays the number of items of information in the data field, allowing any receiver to check whether it has received all the information transferred to it. The data field contains the information that is transferred to other CAN nodes. The “CRC” is the cyclic redundancy check that contains a 15-bit cyclic redundancy check code and a recessive delimiter bit and is used to detect transfer faults. The “ACK” is the acknowledge field in which the receivers signal to the transmitter that they have correctly received the data protocol, and if there is an error, the receivers notify the transmitter, which prompts the transmitter to resend the data protocol. The “EF” is the end field that marks the end of the data protocol and is the last possibility to indicate an error has occurred. If it is determined that the current data is for the dim on/off controller to be on, the application module 220 sends, at step 308, a signal on the micro-LED bus 212 to the basic CAN bus module 201 to turn on the micro-LED unit. If it is determined that the current data is for the dim on/off controller to be off, the application module 220 sends, at step 310, a signal on the micro-LED bus 212 to the basic CAN bus module 201 to turn off the micro-LED unit. If it is determined that the current data is for the dim on/off controller to be dimmed, the application module 220 sends, at step 310, a signal on the micro-LED bus 212 to the basic CAN bus module 201 to dim the micro-LED unit to the corresponding brightness. For example, the micro-LED unit may be dimmed by only activating a portion or percentage of the micro-LEDs in each micro-LED tile 204 to achieve a predetermined brightness level. In some embodiments, the micro-LED headlights adjust brightness based on a variety of factors to enhance visibility and conserve energy. Ambient light conditions play a crucial role, with the system increasing brightness in low-light environments such as twilight or during overcast weather, while reducing it in bright daylight or well-lit urban areas to avoid unnecessary glare and power consumption. Vehicle speed and road type also influence brightness settings. On highways or open roads where higher speeds are common, increased brightness ensures a broader and farther field of vision. Conversely, in urban settings with lower speed limits and more ambient street lighting, the headlights dim to a safer and more energy-efficient level. Weather conditions, such as heavy rain, snow, or fog, necessitate adjustments in brightness to balance visibility with safety. The system minimizes reflection and glare, which are more pronounced under these conditions, by fine-tuning the intensity of the headlights. Traffic density detection allows for adaptive brightness control. In dense traffic, headlights automatically dim to prevent dazzling other drivers, whereas in less congested areas, they brighten to provide better visibility. Battery conservation is especially critical in electric vehicles. The system smartly modulates headlight brightness based on the battery's charge level. For instance, during long journeys with limited charging opportunities, the headlights might operate at a lower intensity to preserve battery life, ensuring sufficient charge for essential vehicle functions. User preferences and driving modes also influence the brightness settings. Modes like ‘Night Mode’ enhance illumination for darker, rural roads, while ‘Eco Mode’ focuses on reducing energy consumption, ideal for city driving where lighting conditions are generally better. Additionally, some embodiments might integrate real-time traffic and navigation data to anticipate lighting needs. For instance, as the vehicle approaches a tunnel or an underpass, the headlights could automatically brighten, and then dim again once the vehicle exits. Similarly, in areas known for wildlife crossings, the headlights could enhance illumination to increase the driver's reaction time to potential hazards. Some embodiments may be specific to the needs and challenges faced by cargo vehicles, such as the increased height of their headlights which can cause more glare for other road users. In these cases, the micro-LED system can automatically adjust the angle of the headlights downwards slightly when in proximity to oncoming traffic or in densely populated areas, effectively reducing glare while maintaining adequate road illumination. Additionally, considering the larger size and unique shape of cargo vehicles, lighting can be strategically placed not only at the front but also along the sides and rear. This distributed lighting approach allows for a more comprehensive illumination of the vehicle's surroundings, enhancing safety during turns, maneuvers in tight spaces, and reversing. The lights work in concert, with side and rear lights brightening as needed, depending on the vehicle's orientation and movement. For cargo vehicles engaged in long-haul travel, adaptive lighting becomes crucial. The system can modify the brightness based on the route, brightening on unlit rural roads for better visibility and dimming on well-lit highways to conserve energy—a feature particularly beneficial for electric cargo vehicles to maximize their range. Another aspect is the dynamic adjustment of headlight intensity and angle based on the vehicle's load. As cargo vehicles often operate under varying load conditions, a heavier load might necessitate a different headlight angle than when the vehicle is unloaded or lightly loaded, ensuring optimal road illumination in all scenarios. Moreover, for cargo vehicles that traverse diverse terrains and weather conditions, the lighting system could be programmed to adjust accordingly. Enhanced intensity and spread of the headlights could be activated in foggy conditions or on snowy roads to compensate for reduced visibility, thus maintaining a high level of safety. Finally, in scenarios where multiple cargo vehicles travel in a convoy, an advanced feature of the lighting system could enable inter-vehicle communication to synchronize their lighting. This ensures optimal visibility for all vehicles in the convoy, with each vehicle's lights adjusting based on their position in the lineup to reduce glare and shadows, thereby enhancing safety for the entire convoy. These specialized lighting strategies for cargo vehicles address the unique challenges posed by their design and usage, ensuring that safety, visibility, and efficiency are maintained across various operating conditions. Then the process returns to continuously polling the memory 208.

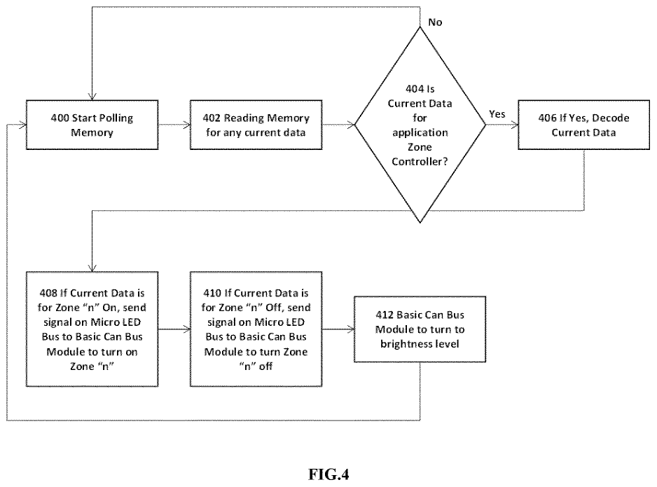

FIG. 4 illustrates an embodiment of a micro-LED CAN bus connection for zone control. The process begins with the application module 220 being executed by the processor 214. The application module 220 begins polling, at step 400, the memory 208. The application module 220 reads, at step 402, the memory 208 for any current data. For example, the application module 220 reads the memory 208, which contains the data messages received by the basic CAN bus module 210. The messages may contain instructions or information about the micro-LED tiles 204 and whether they should be activated, terminated, or adjusted for brightness. The application module 220 determines, at step 404, if the current data is for the application zone controller. If it is determined that the data stored in memory 208 is not for the zone controller, then the process returns to polling the memory 208. If it is determined that the current data is for the zone controller, the application module 220 decodes, at step 406, the current data. For example, the application module 220 may decode the data message structure. The “SF” is the start field that indicates the beginning of a message with a dominant bit and marks the start of the data protocol. The message identifier defines the level of priority of the data protocol. For example, if two CAN nodes send their data protocol simultaneously, the CAN node with the higher priority will take precedence. The lower value for the CAN node indicates a higher priority. The control, which may be the check field, displays the number of items of information in the data field, allowing any receiver to check whether it has received all the information transferred to it. The data field contains the information that is transferred to other CAN nodes. The “CRC” is the cyclic redundancy check that contains a 15-bit cyclic redundancy check code and a recessive delimiter bit and is used to detect transfer faults. The “ACK” is the acknowledge field in which the receivers signal to the transmitter that they have correctly received the data protocol, and if there is an error, the receivers notify the transmitter, which prompts the transmitter to resend the data protocol. The “EF” is the end field that marks the end of the data protocol and is the last possibility to indicate an error has occurred. If it is determined that the current data is for the zone “N” to be on the application module 220 sends, at step 408, a signal on the micro-LED bus 212 to the basic CAN bus module 201 to turn on the micro-LED tiles 204 that is located in the zone “N.” For example, the zones may be specific micro-LED tiles 204 that create the micro-LED panel to be activated, such as the top row may be zone 1, the bottom row may be zone 2, etc. The zones may be a plurality of micro-LED tiles 204 that are predetermined to be grouped together, and the zones may be any combination of micro-LED tiles 204 that create the micro-LED panel, such as in the same column, row, diagonally, every other column, row, or tile, etc. If it is determined that the current data is for the zone controller to be off, the application module 220 sends, at step 410, a signal on the micro-LED bus 212 to the basic CAN bus module 201 to turn off the micro-LED tiles 204 that is located in the zone “N.” For example, the zones may be specific micro-LED tiles 204 that create the micro-LED panel to be terminated, such as the top row may be zone 1, the bottom row may be zone 2, etc. The zones may be a plurality of micro-LED tiles 204 that are predetermined to be grouped together, and the zones may be any combination of micro-LED tiles 204 that create the micro-LED panel, such as in the same column, row, diagonally, every other column, row, or tile, etc. Then the basic CAN bus module 201 adjusts, at step 412, the brightness level of the micro-LED tiles 204 in the zone. For example, the data message received may contain the information for adjusting the micro-LED tiles 204 in the corresponding zone to a certain brightness, such as 20%, 40%, etc. Then the process returns to continuously polling the memory 208.

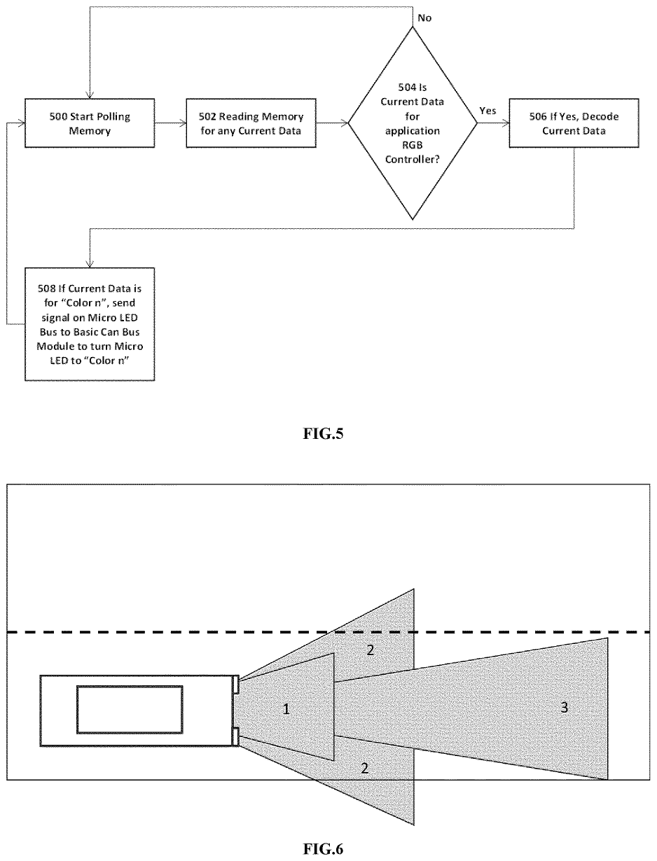

FIG. 5 illustrates an embodiment of a micro-LED CAN bus connection for RGB control. The process begins with the application module 220 being executed by the processor 214. The application module 220 begins polling, at step 500, the memory 208. The application module 220 reads, at step 502, the memory 208 for any current data. For example, the application module 220 reads the memory 208, which contains the data messages received by the basic CAN bus module 210. The messages may contain instructions or information about the micro-LED tiles 204 and whether they should be activated, terminated, or adjusted for brightness. The application module 220 determines, at step 504, if the current data is for the application RGB controller. If it is determined that the data stored in memory 208 is not for the RGB controller then the process returns to polling the memory 208. If it is determined that the current data is for the RGB controller the application module 220 decodes, at step 506, the current data. For example, the application module 220 may decode the data message structure. The “SF” is the start field that indicates the beginning of a message with a dominant bit and marks the start of the data protocol. The message identifier defines the level of priority of the data protocol. For example, if two CAN nodes send their data protocol simultaneously, the CAN node with the higher priority will take precedence. The lower value for the CAN node indicates a higher priority. The control, which may be the check field, displays the number of items of information in the data field, allowing any receiver to check whether it has received all the information transferred to it. The data field contains the information that is transferred to other CAN nodes. The “CRC” is the cyclic redundancy check that contains a 15-bit cyclic redundancy check code and a recessive delimiter bit and is used to detect transfer faults. The “ACK” is the acknowledge field in which the receivers signal to the transmitter that they have correctly received the data protocol, and if there is an error, the receivers notify the transmitter, which prompts the transmitter to resend the data protocol. The “EF” is the end field that marks the end of the data protocol and is the last possibility to indicate an error has occurred. If it is determined that the current data is for a specific color to be activated on the micro-LED tile 204, the application module 220 sends, at step 508, a signal on the micro-LED bus 212 to the basic CAN bus module 201 to adjust the micro-LED tiles 204 to the specific color. For example, a data message may contain information on a specific color, which may be created using a certain amount of the RGB LEDs in the micro-LED to produce a specific light, such as red, green, blue, etc. Then the process returns to continuously polling the memory 208.

FIG. 6 illustrates three examples of smart headlight patterns, each suitable for different driving conditions, with a smart system in place to select the appropriate pattern based on environmental inputs and driving scenarios. Pattern 1, showing the shortest range of illumination, would be apt for conditions where full-beam intensity is not required. This could include scenarios like twilight hours where natural light is still present, or in well-lit urban areas where additional light intensity may contribute to light pollution or glare. Additionally, this setting can be beneficial for conserving energy in electric vehicles, where efficient power management is crucial. Pattern 2, with a medium range and a wider spread, the system might engage this configuration in suburban areas or on secondary roads. It's beneficial when the vehicle requires a balance between distance and breadth of illumination, allowing for the detection of roadside pedestrians and obstacles without extending the beam too far into the distance, which can be unnecessary in moderately lit conditions. Pattern 3 projects the longest and most focused beam, designed for the darkest conditions and higher-speed travel. On unlit rural roads, highways, or in conditions of poor visibility, such as heavy rain or fog, this pattern would enhance the driver's visibility significantly. The extended reach of the beam helps in detecting obstacles or road changes from a greater distance, providing additional reaction time at high speeds. A smart headlight system could use an array of sensors to assess the ambient light levels, weather conditions, vehicle speed, and even the presence of other road users to decide which headlight pattern is most appropriate. The system would seamlessly transition between these patterns, or perhaps even blend aspects of them, to ensure the best possible visibility without compromising safety or efficiency. For instance, as natural light diminishes at dusk, the system may shift from the first to the second pattern, and as full darkness sets in or as the vehicle accelerates onto an open road, it may transition to the third pattern to provide maximum visibility.

The functions performed in the processes and methods may be implemented in differing orders. Furthermore, the outlined steps and operations are only provided as examples, and some of the steps and operations may be optional, combined into fewer steps and operations, or expanded into additional steps and operations without detracting from the essence of the disclosed embodiments.

1. A method to integrate a micro-LED unit with CAN bus, comprising;
having a substrate;
having a plurality of micro-LEDs;
having a CAN bus module;
having a memory;
having a processor; and
having a CAN bus, wherein, the CAN bus module is continuously polling to start, reads a data message received from the CAN bus, stores the data in memory, determines the appropriate controller for micro-LED tiles, and activates, terminates, or adjusts the settings of the micro-LED tile.

2. The method of claim 1, wherein the CAN bus module included the substrate, a micro-LED tile, a CAN bus tile, the memory, another CAN bus module, a bus controller, the processor, CAN bus twisted pair, a CAN bus controller and decoder, and a CAN bus application module.

3. The method of claim 1, wherein the substrate is made of glass, silicon or plastics wherein further the substrate has active electronic components such as but not limited to transistors, resistors, capacitors, or any other electronic component commonly used in a system substrate.

4. The method of claim 1, wherein the substrate has electrical signal rows and columns.

5. The method of claim 1, wherein the substrate is a sapphire substrate with LED layers grown monolithically on top of it, and the substrate is a backplane with a circuitry to derive Micro-LED devices.

6. The method of claim 1, wherein the substrate is a flexible or rigid substrate.

7. The method of claim 2, wherein Micro-LED tile contains a plurality of miniature LED (light emitting diodes) arrays, with each Micro-LED functioning as a pixel and is driven to emit light.

8. The method of claim 7, wherein the Micro-LEDs comprise several microscopic LEDs, which self-illuminate per display pixel.

9. The method of claim 8, wherein panels are made up of a series of tiny red, green, and blue micro-LEDs and are connected together to make one larger whole.

11. The method of claim 9, wherein the Micro-LED tile is produced in a plurality of sizes to increase a width or a length of the Micro-LED tile.

12. The method of claim 10, wherein, the Micro-LED tiles include a plurality of connectors which are an electrochemical device used to create an electrical connection between the plurality of Micro-LED, which create the Micro-LED tile.

13. The method of claim 12, wherein the connectors receive power, data signals, informational instructions from a ribbon connector to power and control the individual Micro-LEDs in the Micro-LED tiles.

14. The method of claim 7, wherein the CAN bus tile is integrated with the micro-LED tile to send and receive instructions from other vehicle applications, devices, and controllers.
